(19) United States
(12) Patent Application Publication
(10) Pub. No.: US 2008/0237850 A1
(43) Pub. Date: Oct. 2, 2008

(54) COMPLIANT BUMP STRUCTURE AND BONDING STRUCTURE

(75) Inventor: Shyh-Ming Chang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 11/868,948

(22) Filed: Oct. 8, 2007

(30) Foreign Application Priority Data
Mar. 30, 2007 (TW) 96111252

(51) Int. Cl. H01L 23/48; H01L 21/00

(52) U.S. Cl. 257/737; 438/107; 257/E23.021

(57) ABSTRACT

A compliant bump structure includes a substrate, at least a first polymer bump, at least a second polymer bump and at least a conductive layer. The substrate has at least a pad on a surface thereof. The first polymer bump is disposed on the pad. The second polymer bump is disposed on the surface of the substrate outside the pad. The conductive layer is disposed on the first and second polymer bumps.

### CROSS-REFERENCE TO RELATED APPLICATION

This application claims the priority benefit of Taiwan application serial no. 96111252, filed on Mar. 30, 2007. All disclosure of the Taiwan application is incorporated herein by reference.

### BACKGROUND OF THE INVENTION

1. Field of the Invention

The present invention is related to a bonding structure which utilizes a conductive layer on compliant bumps to electrically connect two substrates.

2. Description of Related Art

Nowadays chips are mostly fabricated by silicon wafers. A plurality of chips is formed after silicon wafers undergo a semiconductor process and a cutting process. The chips need to be packaged on a package substrate and be further assembled on electronic products (such as computers, mobile phones or liquid crystal display devices) via the package substrate, or be directly assembled with a circuit board (a chip on wiring board, COB, for example) or a glass substrate (a chip on glass, COG, for example). The chips would then function properly.

Usually, the chips are electrically connected to the circuit board, the package substrate or the glass substrate by a flip chip technology or a wire bonding technology. As far as the flip chip technology is concerned, a plurality of metal pads of the chip are connected to a plurality of pads on the package substrate, the circuit board or the glass substrate by solder or metal bumps, and then the chip is assembled on the package substrate, the circuit board or the glass substrate.

FIGS. 1A and 1B illustrate a conventional chip connected to a substrate. Referring to both FIGS. 1A and 1B, a chip 110 has a plurality of metal pads 112, and a plurality of metal bumps 120 disposed on the metal pads 112 respectively. A substrate 140 has a plurality of metal pads 142, wherein the substrate 140 may be a glass substrate or a package substrate. An anisotropic conductive film (ACF) 150 having a plurality of conductive particles 152 therein is disposed between the chip 110 and the substrate 140. A heating process and a pressurizing process are performed on the ACF 150. The ACF 150 thus connects the chip 110 to the substrate 140, and the metal pads 112 are electrically connected to the metal pads 142 respectively through the conductive particles 152. During the heating process and the pressurizing process of the ACF 150, the ACF 150 would start flowing after being heated such that some conductive particles 152 are lost. However, the loss would increase the resistance between the metal pads 112 and the metal pads 142 and it even causes a broken circuit between some of the metal pads 112 and the corresponding metal pads 142.

### SUMMARY OF THE INVENTION

The present invention provides a compliant bump structure including a substrate, at least a first polymer bump, at least a second polymer bump and at least a conductive layer. The substrate has at least a pad located on a surface of the substrate. The first polymer bump is disposed on the pad. The second polymer bump is disposed on the surface outside the pad of the substrate. The conductive layer is disposed on the first polymer bump and the second polymer bump.

The invention further provides a bonding structure including a first substrate, at least a first polymer bump, at least a second polymer bump and at least a conductive layer and a second substrate. The first substrate has at least a first pad located on a surface thereof. The first polymer bump is disposed on the first pad. The second polymer bump is disposed on the surface outside the pad of the first substrate. The conductive layer is disposed on the first polymer bump and the second polymer bump. The second substrate has at least a second pad located on a surface of the second substrate. The conductive layer is connected to the second pad.

The invention also provides a bonding process. A compliant bump structure including a substrate, at least a first polymer bump, at least a second polymer bump and at least a conductive layer is provided. The substrate has at least a first pad located on a surface of the substrate. The first polymer bump is disposed on the pad. The second polymer bump is disposed on the surface outside the pad of the substrate. The conductive layer is disposed on the first polymer bump and the second polymer bump. Afterwards, a second substrate is provided. The second substrate has at least a second pad located on a surface of the second substrate. Next, the conductive layer is connected to the second pad.

### BRIEF DESCRIPTION OF THE DRAWINGS

FIGS. 1A and 1B illustrate a conventional chip connected to a substrate.

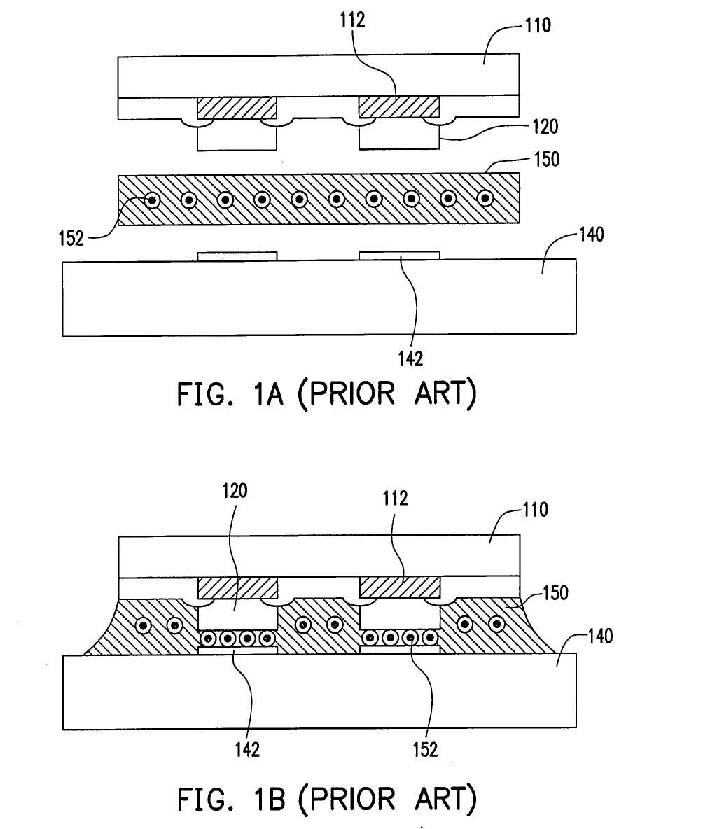

FIG. 2 is a top view of a compliant bump structure according to one embodiment of the present invention.

FIG. 3 is a cross-sectional view of the compliant bump structure of FIG. 2 along line A-A.

FIGS. 4A and 4B respectively illustrate the views of the compliant bump structure and the substrate of FIG. 3 before and after they are connected.

FIG. 5 is a top view of a compliant bump structure according to another embodiment of the invention.

FIG. 6 is a cross-sectional view of the compliant bump structure of FIG. 5 along line B-B.

FIGS. 7A and 7B respectively illustrate the views of the compliant bump structure and the substrate of FIG. 6 before and after they are connected.

### DESCRIPTION OF EMBODIMENTS

The same reference numerals represent the same or similar elements in the following embodiments.

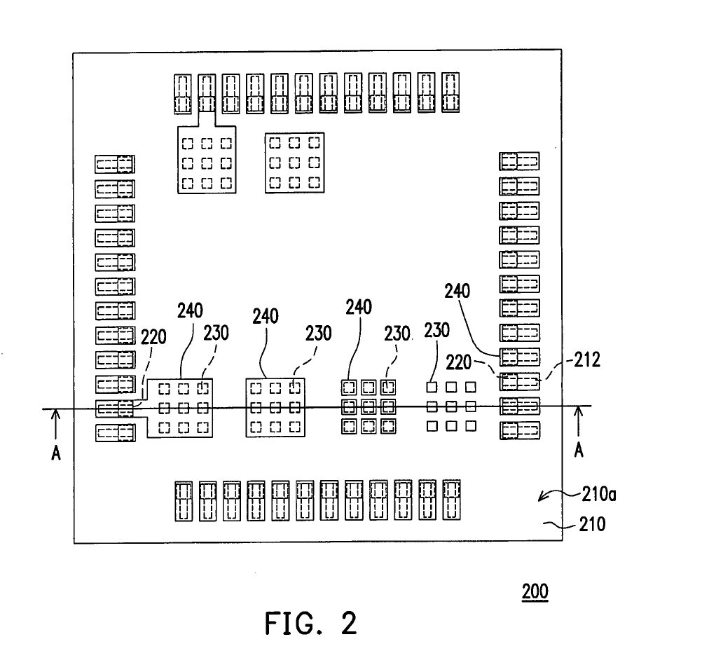

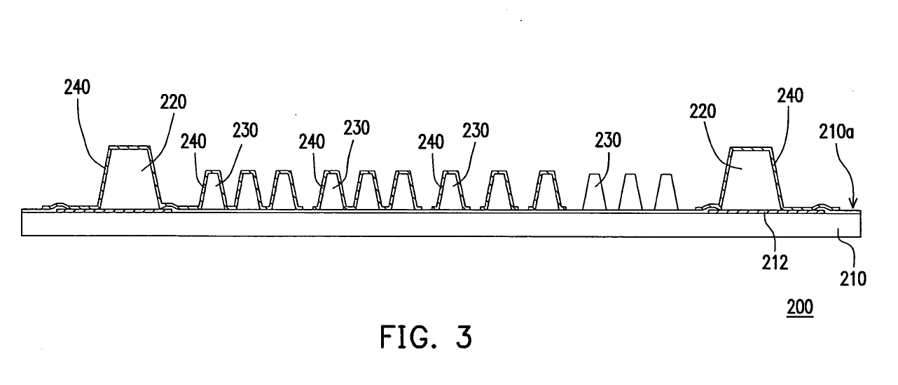

FIG. 2 is a top view of a compliant bump structure according to one embodiment of the invention. FIG. 3 is a cross-sectional view of the compliant bump structure of FIG. 2 along line A-A. Referring to FIGS. 2 and 3, a compliant bump structure 200 includes a first substrate 210, which may be a chip, a rigid circuit board, a flexible substrate, a glass substrate or a ceramic substrate. The first substrate 210 has a plurality of first pads 212 located on a surface 210a thereof. The compliant bump structure 200 further includes a plurality of first polymer bumps 220, a plurality of second polymer bumps 230 and a conductive layer 240. The first polymer bumps 220 are disposed on the first pads 212 respectively. The second polymer bumps 230 are disposed on the surface 210a outside the first pad 212 of the substrate 210. The conductive layer 240 is disposed on the first polymer bumps 220 and the second polymer bumps 230.

In the present embodiment, a portion of the conductive layer 240 on at least one of the first polymer bumps 220 may be connected to another portion of the conductive layer 240 on at least one of the second polymer bumps 230. In addition, at least two portions of the conductive layer 240 respectively on at least two of the second polymer bumps 220 may be connected. Moreover, the height of the second polymer bumps 230 relative to the substrate 210 may be smaller than that of the first polymer bumps 220 relative to the substrate 210.

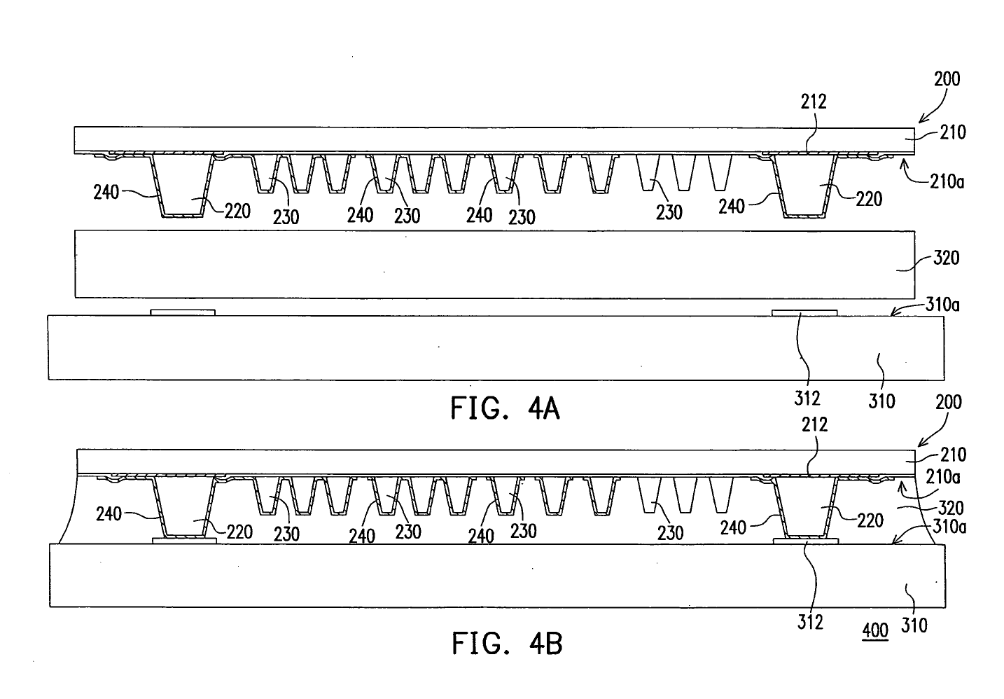

FIGS. 4A and 4B respectively illustrate the views of the compliant bump structure and the substrate of FIG. 3 before and after they are connected. Referring to FIG. 4A, the compliant bump structure 200 is connected to a second substrate 310 with a bonding adhesive 320 so as to form a bonding structure 400 as shown in FIG. 4B. In the present embodiment, the second substrate 310 may be a chip, a rigid circuit board, a flexible substrate, a glass substrate or a ceramic substrate. The second substrate 310 has a plurality of second pads 312 located on a surface 310a thereof. The conductive layer 240 is connected to the second pads 312.

During the bonding process, the bonding adhesive 320 is first disposed between the first substrate 210 and the second substrate 310. Thereafter, the bonding adhesive 320 is softened, and the first substrate 210 and the second substrate 310 are compressed. As a result, the bonding adhesive 320 fills the space between the first substrate 210 and the second substrate 310, and portions of the conductive layer 240 penetrate through the bonding adhesive 320 and are connected to the second pads 312 respectively. Finally, the bonding adhesive 320 is cured. The method for curing the bonding adhesive 320 may be a heating process, an ultraviolet irradiation process, an ultrasonic-wave vibration process or an infrared irradiation process, or at least two of the aforementioned methods may be applied simultaneously.

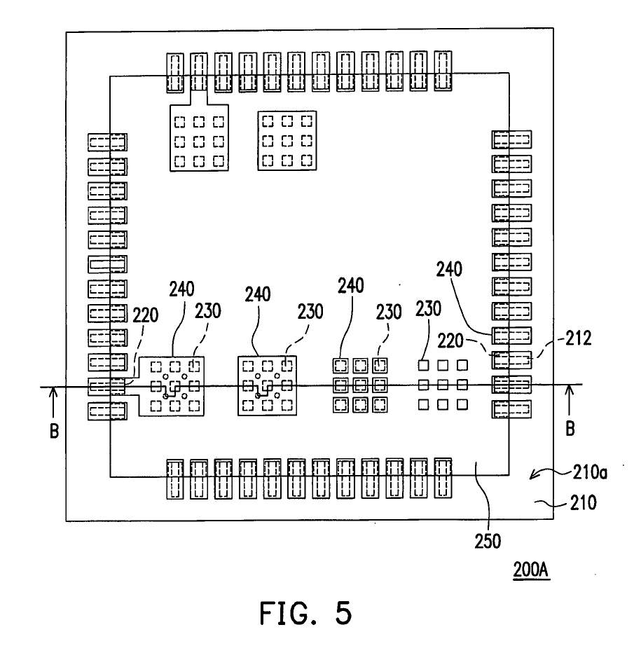

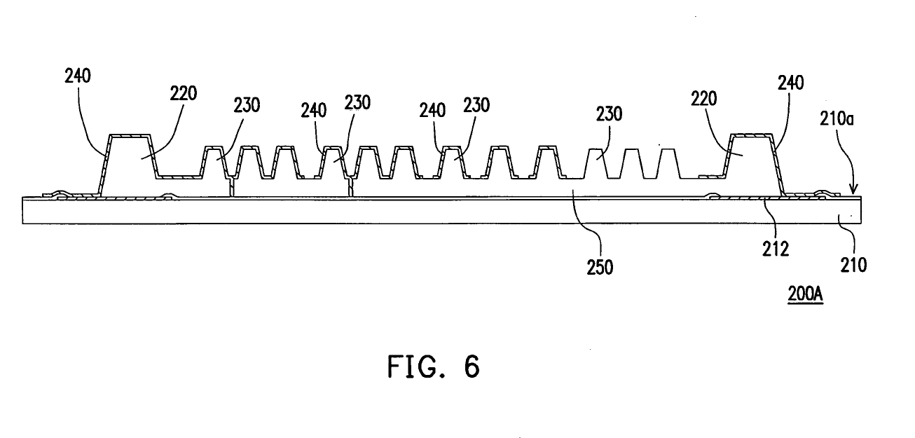

FIG. 5 is a top view of a compliant bump structure according to another embodiment of the invention. FIG. 6 is a cross-sectional view of the compliant bump structure of FIG. 5 along line B-B. Referring to FIGS. 5 and 6, in comparison with the compliant bump structure 200 of FIGS. 2 and 3, a compliant bump structure 200A further includes a polymer protective layer 250 disposed on the surface 210a outside the pads 212 of the substrate 210. The second polymer bumps 240 are disposed on the polymer protective layer 250. Therefore, the first polymer bumps 220 are connected to the second polymer bumps 230 through the polymer protective layer 250. Furthermore, at least two of the second polymer bumps 230 are connected through the polymer protective layer 250.

In the present embodiment, the polymer protective layer 250 and the second polymer bumps 230 may be integrally formed. Additionally, the first polymer bumps 220 may also be integrally formed with the polymer protective layer 250 and the second polymer bumps 230. Besides, portions of the conductive layer 240 may further penetrate through the polymer protective layer 250 and be connected to the surface 210a of the substrate 210.

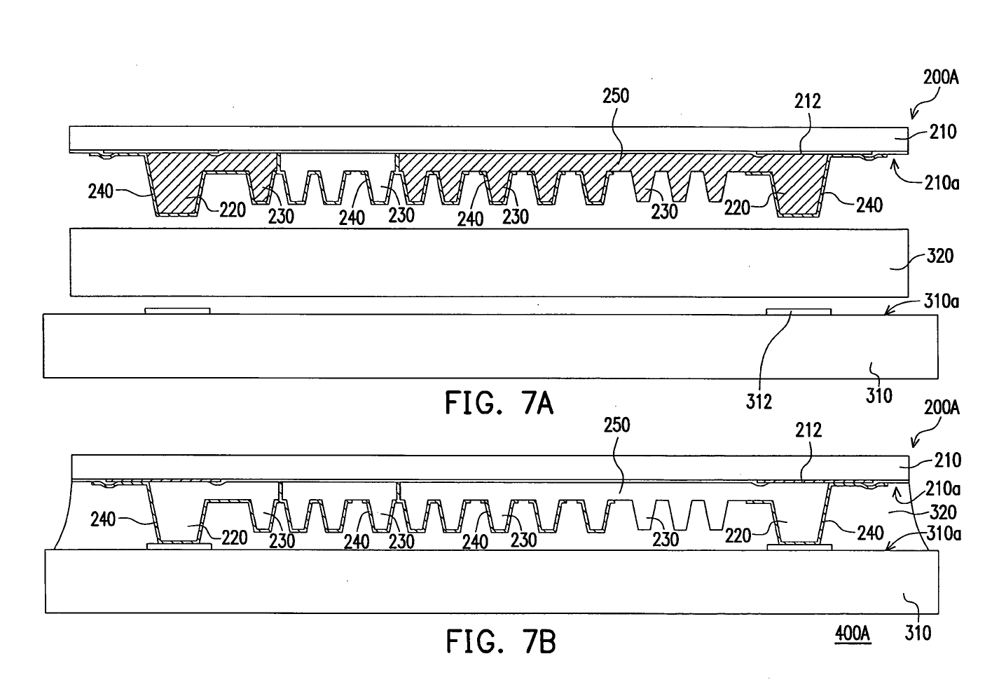

FIGS. 7A and 7B respectively illustrate the views of the compliant bump structure and the substrate of FIG. 6 before and after they are connected. Referring to FIG. 7A, the compliant bump structure 200A is connected to a second substrate 310 with a bonding adhesive 320 so as to form a bonding structure 400A as shown in FIG. 7B.

To sum it up, in the present invention, the first pads of the first substrate are electrically connected to the second pads of the second substrate with a plurality of first polymer bumps and portions of the conductive layer located on the first polymer bumps respectively. Further, the pressure generated during the bonding process of the first and second substrates is distributed by the second polymer bumps in the invention. Consequently, the conductive layer is prevented from chapping so as to ensure its connection to the second pads. In addition, the conductive layer disposed on the second polymer bumps further has the function of heat conductivity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A compliant bump structure, comprising:
a substrate having at least a pad located on a surface of the substrate;
at least one first polymer bump disposed on the pad;
at least one second polymer bump disposed on the surface outside the pad of the substrate; and
at least one conductive layer disposed on the first polymer bump and the second polymer bump.

2. The compliant bump structure as claimed in claim 1, wherein portions of the conductive layer on at least one of the first polymer bumps and the conductive layer on at least one of the second polymer bumps respectively are connected.

3. The compliant bump structure as claimed in claim 1, wherein portions of the conductive layer on at least two of the second polymer bumps respectively are connected.

4. The compliant bump structure as claimed in claim 1, wherein the height of the second polymer bump relative to the substrate is smaller than the height of the first polymer bump relative to the substrate.

5. The compliant bump structure as claimed in claim 1, wherein the first polymer bump is connected with the second polymer bump.

6. The compliant bump structure as claimed in claim 1, further comprising:
a plurality of second polymer bumps and at least two of the second polymer bumps connected.

7. The compliant bump structure as claimed in claim 1, further comprising:
a polymer protective layer disposed on the surface outside the pad of the substrate and the second polymer bump disposed thereon.

8. The compliant bump structure as claimed in claim 7, wherein the polymer protective layer and the second polymer bump are integrally formed.

9. The compliant bump structure as claimed in claim 7, wherein the conductive layer penetrates through the polymer protective layer to be connected to the surface of the substrate.

10. The compliant bump structure as claimed in claim 1, wherein the substrate is a chip, a rigid circuit board, a flexible substrate, a glass substrate or a ceramic substrate.

11. A bonding structure, comprising:
a first substrate having at least a first pad located on a surface thereof;
at least a first polymer bump disposed on the first pad;
at least a second polymer bump disposed on the surface outside the pad of the first substrate;
at least a conductive layer disposed on the first polymer bump and the second polymer bump; and
a second substrate having a least a second pad located on a surface of the second substrate, wherein the conductive layer is connected to the second pad.

12. The bonding structure as claimed in claim 11, wherein the first substrate is a chip, a rigid circuit board, an flexible substrate, a glass substrate or a ceramic substrate.

13. The bonding structure as claimed in claim 11, wherein the second substrate is a chip, a rigid circuit board, an flexible substrate, a glass substrate or a ceramic substrate.

14. The bonding structure as claimed in claim 11, further comprising:
a bonding adhesive disposed between the first substrate and the second substrate so as to connect the first substrate to the second substrate.

15. A bonding process, comprising:
providing a compliant bump structure, comprising:
a first substrate having at least a first pad located on a surface of the first substrate;
at least a first polymer bump disposed on the first pad;
at least a second polymer bump disposed on the surface outside the pad of the first substrate; and
at least a conductive layer disposed on the first polymer bump and the second polymer bump;
providing a second substrate having at least a second pad located on a surface of the second substrate; and
connecting the conductive layer to the second pad.

16. The bonding process as claimed in claim 15, wherein the step of connecting the conductive layer to the second pad comprises:
disposing a bonding adhesive between the first substrate and the second substrate;
softening the bonding adhesive;
pressing the first substrate and the second substrate so as to fill the space between the first substrate and the second substrate with the bonding adhesive, the conductive layer penetrating through the bonding adhesive to be connected with the second pad; and curing the bonding adhesive.

17. The bonding process as claimed in claim 16, wherein the method for curing the bonding adhesive is a heating process, an ultraviolet irradiation process, an ultrasonic-wave vibration process or an infrared irradiation process, or at least two of the aforementioned methods are applied simultaneously.
